(19) United States
(12) Patent Application Publication
(10) Pub. No.: US 2010/0053535 A1
(43) Pub. Date: Mar. 4, 2010

(54) DISPLAY APPARATUS AND METHOD OF FABRICATION THE SAME

(76) Inventors: JONG-SEONG KIM, Seoul (KR); Min-Ho Yoon, Seoul (KR)

Correspondence Address: F. CHAU & ASSOCIATES, LLC, 130 WOODBURY ROAD, WOODBURY, NY, 11797, US

(21) Appl. No.: 12/412,769

(22) Filed: Mar. 27, 2009

(30) Foreign Application Priority Data
Aug. 26, 2008 (KR) 10-2008-0083454

(51) Int. Cl. G02F 1/1339; H05K 1/03; G02F 1/13

(52) U.S. Cl. 349/155; 174/254; 349/187

(57) ABSTRACT

Disclosed is a display apparatus. The display apparatus includes a first substrate having a plurality of pixels and a second substrate facing the first substrate. A concave-convex section is formed on at least one of the first and second substrates. The substrate having the concave-convex section is a flexible substrate. The substrate integrally formed with the concave-convex section is manufactured by applying a transfer method to an FRP substrate.

### CROSS-REFERENCE TO RELATED APPLICATION

This application relies for priority upon Korean Patent Application No. 2008-83454 filed on Aug. 26, 2008, the contents of which are herein incorporated by reference in their entirety.

### BACKGROUND OF THE INVENTION

1. Technical Field

The present invention relates to a display apparatus. More particularly, the present invention relates to a display apparatus including a flexible substrate formed with a press-plate having a concave-convex pattern.

2. Discussion of the Related Art

Since demands for various display apparatuses have been increased with the development of an information-related society, research into flat panel display apparatuses such as liquid crystal displays (LCDs) and plasma display panels (PDPs) has been actively carried out. Among them, the LCDs are capable of mass production, use a relatively simple driving scheme and produce high quality images.

An LCD includes a liquid crystal layer having liquid crystal molecules interposed between two transparent substrates, and controls the orientation of the liquid crystal molecules to adjust light transmittance in each pixel, thereby displaying a desired image.

A conventional LCD may use a ball spacer or a column spacer to maintain distance (i.e. cell gap) between the two transparent substrates.

However, conventional ball spacers may be aggregated due to differences in interfacial properties between an alignment layer on each of the two substrates. As a result, alignment defects may occur. The alignment defects may cause surface deformation to occur due to pressure applied to the spacers when the LCD is assembled in a later process.

In this regard, a column spacer has also been developed. However, to form the column spacer, additional processes, such as photolithography or attaching a film including a transfer film and exposing the transfer film, are necessary.

Further, a partition surrounding a color filter may be formed and an additional photolithography process may be used to form the partition.

In addition, although a conventional LCD is a kind of a flat panel display apparatus, the fields to which the LCD can be applied can be limited. In this regard, there is a demand for a more flexible LCD applicable to various fields.

Thus, there is a need for an efficient LCD capable of preventing the defects associated with the use of a conventional spacer, simplifying the fabrication process by omitting the additional process of forming the color filter, and satisfying the demand for an LCD that can be more broadly applied.

### SUMMARY OF THE INVENTION

Therefore, the embodiments of the present invention provide a high quality display apparatus capable of simplifying the fabrication process, reducing fabrication costs, and minimizing defects by forming a concave-convex section as a whole on a flexible substrate, and a method of fabrication the same.

According to an embodiment of the present invention, a display apparatus includes a first substrate having a plurality of pixels, a second substrate facing the first substrate, and a concave-convex section integrally formed on at least one of the first and second substrates.

The substrate having the concave-convex section includes a flexible substrate. The flexible substrate may include a plastic substrate. The flexible substrate may include a fiber reinforced plastic (FRP) substrate having a low refractive index and temperature expansion coefficient.

The concave-convex section may be a spacer that maintains a cell gap between the first and second substrates. In such a case, the spacer may be formed on the first or second substrate. The spacer may be formed on one of the first substrate and the second substrate that does not include thin film transistors formed thereon. Since the spacer is integrally formed on the substrate, the spacer may be provided on a substrate fabricated with relatively less manufacturing processes and having less step differences between other structures. Thus, when the first substrate includes the thin film transistor and the second substrate includes a color filter, the spacers may be formed on the second substrate.

The spacers may have various heights. For example, two spacers may have two different heights. The spacers may have various shapes such as cylindrical and hexahedral shapes and may have heights of about 2 μm to about 10 μm and widths of about 2 μm to about 20 μm.

A plurality of spacers can be provided at random positions or at predetermined positions. For example, in a transflective type LCD, the spacers can be provided only in a region blocked by a black matrix or in a reflecting region thereof.

The concave-convex section is formed on a surface of the second substrate and may include a convex section formed at a peripheral region of each pixel. A color filter can be formed on the pixel surrounded by the convex section.

The concave-convex section can be formed on two surfaces of the second substrate. A convex section as a partition can be formed at a peripheral region of each pixel on one surface of the second substrate and a concave section corresponding to the partition can be formed on the other surface A black matrix can be formed on the concave section to block light in an area except for a pixel area.

A display apparatus according to an embodiment of the present invention includes an LED (light emitting diode), an OLED (organic LED) and a PDP as well as an LCD. Further, embodiments of the present invention include a display apparatus having a structure protruding from a flexible substrate to perform a predetermined function.

According to an embodiment of the present invention, a first substrate having a plurality of pixels and a second substrate facing the first substrate are prepared. At least one of the first and second substrates is formed by preparing a preliminary substrate, and forming concave-convex sections on the preliminary substrate by using a transfer process.

The concave-convex sections can be formed on one surface or two surfaces of the preliminary substrate. A convex section may be formed on one surface to surround each pixel and a concave section recessed in the pixel may be formed on the other surface.

A color filter can be formed in a pixel surrounded by the convex section using an inkjet method and a black matrix can be formed in the concave section.

The preliminary substrate is compressed by a press plate having a concave-convex pattern thereon. The concave-convex pattern is transferred onto the preliminary substrate by compressing the preliminary substrate by using the press plate. The preliminary substrate having the transferred pattern is cured by heating to form the concave-convex section. The transferring and the curing steps can be simultaneously performed.

A thin film transistor can be formed on the first substrate and a color filter can be formed on the second substrate, and a display apparatus can be formed by combining the first and second substrates.

According to the embodiments of the present invention, a predetermined number of spacers maintaining a cell gap between two substrates, and a predetermined number of concave-convex sections used as partitions surrounding a color filter can be disposed at proper positions with suitable sizes and shapes. In addition, when an LCD is used as the display apparatus, the structure can be directly formed in the process of preparing a substrate in one process without performing an additional process of forming the spacer or the partition.

Further, when the concave-convex section serves as a spacer, the display apparatus can be applied to a touchscreen panel by adjusting heights of the spacers differently and a transflective type LCD by adjusting positions of the spacers.

Since the spacer is integrally formed on the substrate, defects of a conventional ball spacer, for example, local alignment defects or surface deformation due to pressure when an LCD is assembled, can be overcome. Further, endurance against pressure or strikes during a reliability test can be increased.

A conventional partition or wall for a column spacer or a color filter has been manufactured using a photolithography process. In such a case, a lateral side of a spacer may not be formed according to an original design after performing a separation process for a photoresist or a subsequent etching process. Particularly, a width of a lower surface of the partition aligned closely to the substrate may be larger than the width of an upper surface thereof. However, since the spacer of the LCD according to the embodiments of the present invention is formed using a transfer method, the concave-convex section can be formed according to the original design.

The spacers of the LCD according to the embodiments of the present invention can be simultaneously formed with the process of fabricating an FRP substrate, and an additional process, such as a conventional photolithography process for forming a concave-convex section, is not necessary.

As described above, the embodiments of the present invention can provide a high quality display apparatus, simplify the fabrication process, improve the fabrication efficiency and reduce fabrication cost.

### BRIEF DESCRIPTION OF THE DRAWINGS

The embodiments of the present invention will become readily apparent by reference to the following detailed description when considered in conjunction with the accompanying drawings wherein:

FIG. 1 is a plan view illustrating an LCD according to an exemplary embodiment of the present invention;

FIG. 2 is a sectional view illustrating the LCD taken along line II-II′ in FIG. 1, according to an exemplary embodiment of the present invention;

FIG. 3 is a sectional view illustrating an LCD according to an exemplary embodiment of the present invention;

FIGS. 4A to 4C are perspective views illustrating various shapes of a spacer according to exemplary embodiments of the present invention;

FIG. 5 is a sectional view illustrating an LCD according to an exemplary embodiment of the present invention;

FIG. 6 is a sectional view illustrating an LCD according to an exemplary embodiment of the present invention;

FIGS. 7A to 7C are sectional views illustrating a process for preparing a second substrate having a spacer, according to an exemplary embodiment of the present invention;

FIG. 8 is a sectional view illustrating an LCD according to an exemplary embodiment of the present invention; and

FIG. 9 is a sectional view illustrating an LCD according to an exemplary embodiment of the present invention.

### DESCRIPTION OF THE EMBODIMENTS

Hereinafter, a display apparatus according to embodiments of the present invention will be explained in detail with reference to the accompanying drawings.

It is to be understood that the present invention should not be limited to the following exemplary embodiments but various changes and modifications can be made by one with ordinary skill in the art within the spirit and scope of the present invention. The embodiments of the present invention may include various display apparatuses such as LEDs, OLEDs and PDPs. For the convenience of explanation, an LCD will be described as an exemplary embodiment of the present invention.

In the figures, reference numerals may refer to the same or equivalent parts of the embodiments of the present invention throughout the figures of the drawing. As used herein, the expression, “one layer (film) is formed (disposed) ‘on’ another layer (film)” includes not only a case where the two layers (films) are in contact with each other but also a case where an additional layer (film) is present between the two layers (film).

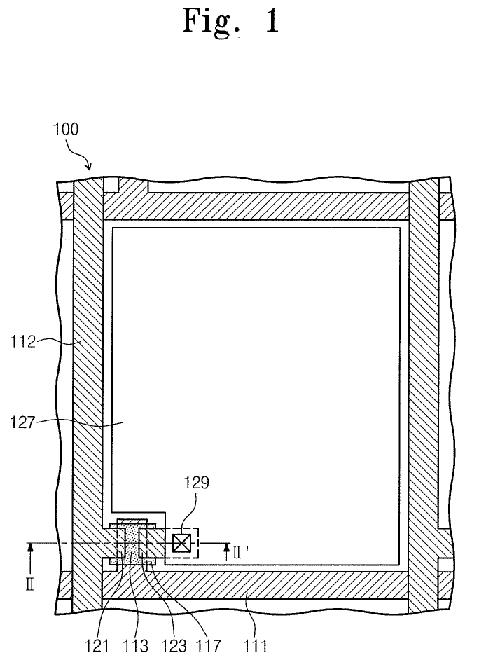

FIG. 1 is a plan view schematically illustrating a part of an LCD according to an exemplary embodiment of the present invention and shows an example wherein a concave-convex section is used as a spacer.

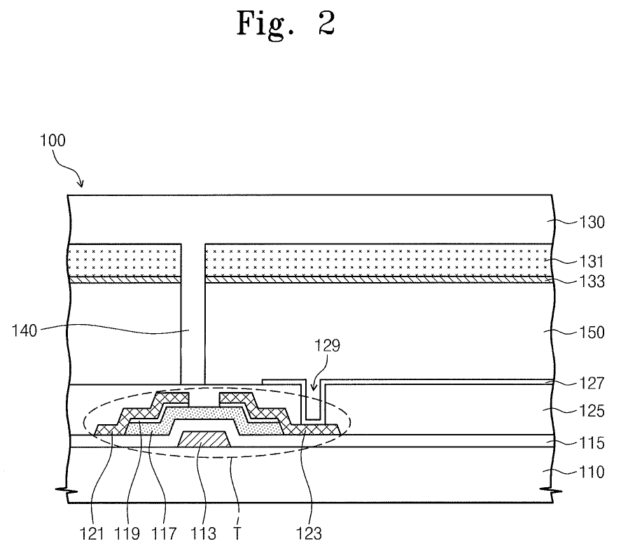

FIG. 2 is a sectional view schematically illustrating an LCD according to an exemplary embodiment of the present invention, which is taken along line II-II′ in FIG. 1.

In the LCD, a plurality of pixels are provided in regions where a plurality of gate lines 111 cross a plurality of data lines 112. One pixel is representatively described.

As illustrated in FIGS. 1 and 2, the LCD 100 includes transparent insulating substrates, i.e. a first substrate 110 and a second substrate 130 that face each other. The second substrate 130 includes a spacer 140 formed on the second substrate 130. A liquid crystal layer 150 having liquid crystal molecules is formed between the first and second substrates 110 and 130.

The gate lines 111 and the data lines 112 are arranged in longitudinal and transverse directions on the first substrate 110 to define the pixels. A thin film transistor T is formed in a pixel area. Each pixel includes a pixel electrode 127 that is connected with the thin film transistor T to drive liquid crystal molecules, together with a common electrode 133 on the second substrate 130.

The thin film transistor T includes a gate electrode 113 connected with the gate line 111, a source electrode 121 connected with the data line 112, and a drain electrode 123 connected with the pixel electrode 127. Further, the thin film transistor T includes a gate insulating layer 115 which isolates the gate electrode 113 from the source and drain electrodes 121 and 123, an active layer 117 which forms a conductive channel between the source electrode 121 and the drain electrode 123 according to gate voltage supplied to the gate electrode 113, and an ohmic contact layer 119.

A protective layer 125 is formed on the thin film transistor T. The protective layer 125 includes a contact hole 129, which exposes a part of the drain electrode 123, so that the pixel electrode 127 is connected to the drain electrode 123 through the contact hole 129.

A color filter 131, which produces red, green and blue colors in each pixel, is formed on the second substrate. The common electrode 133 forming an electric field between the two substrates 110 and 130 together with the pixel electrode 127 of the first substrate 110 is formed on the color filter 131. The common electrode 133 is formed on an area except for the spacer 140 such that the common electrode 133 is spaced apart from the pixel electrode 127.

In embodiments of the present invention, the common electrode 133 can have different patterns. In more detail, as illustrated in FIG. 2, the common electrode 133 can be formed on an area except for the spacer 140.

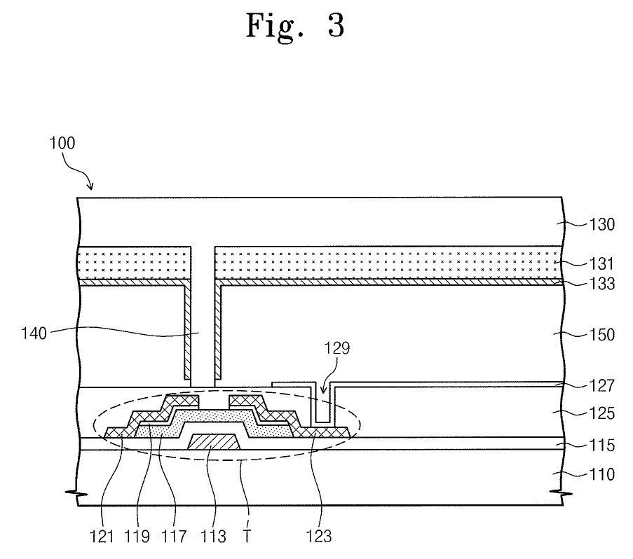

Alternatively, referring to FIG. 3, the common electrode 133 can also be formed on a lateral side of the spacer 140. The embodiment illustrated in FIG. 3 is identical to the embodiment of FIG. 2, except that the common electrode 133 is also formed on a lateral side of the spacer 140. Moreover, since the pixel electrode 127 and the common electrode 133 are spaced apart from each other, the common electrode 133 does not extend to where the spacer 140 meets the protective layer 125 in order to avoid direct contact to the upper surface of the first substrate 110 as illustrated in FIG. 3.

Although not shown in FIG. 3, the spacer 140 may be provided on the upper surface of the first substrate 110 which has no pixel electrode 127. In such a case, the common electrode 133 is formed on the entire surface of the second substrate 130 including the spacer 140.

In the LCD 100, the thin film transistor T supplies a pixel signal from the data line 112 to the pixel electrode 127 in response to a scan signal from the gate line 111, while common voltage is supplied to the common electrode 133, to control the orientation of the liquid crystal molecules. As a result, the electric field is formed between the common electrode 133 and the pixel electrode 127 and the liquid crystal molecules are rotated by the electric field, so that the amount of transmitted light is controlled and thus an image is displayed.

The spacer 140 may be formed on the first or second substrate 110 or 130. A mounting process for a thin film transistor may require many film forming and patterning steps as compared with a color filter process. Since formation of the spacer 140 is affected by step differences on the substrate surfaces, the spacer 140 may be more easily formed on the second substrate 130, wherein a relatively smaller number of process steps are required. However, positions of the thin film transistor T, the color filter 131 and other structures are not limited to those depicted and described above. In detail, the thin film transistor T, the color filter 131 and other structures can be formed at positions different from those of the above-described embodiments.

The two substrates 110 and 130 are flexible substrates, such as plastic substrates. However, some plastic substrates may not be suitable due to their high temperature expansion coefficients and birefringence. If the temperature expansion coefficient is too high, the substrate may be excessively contracted or expanded during a process, and defects, such as misalignment or bending, may occur. If the birefringence is too high, the display quality may be degraded due to light leakage during a normal driving operation. Thus, a suitable material for the substrates 110 and 130 is, for example, a fiber reinforced plastic (FRP), which is manufactured by pre-impregnating organic resin, such as epoxy resin, into yarn or cloth using glass fibers.

The FRP has a temperature expansion coefficient and birefringence lower than those of general plastic. Particularly, when using E-glass as the glass fiber, the FRP has a temperature expansion coefficient of 20 ppm or less. When using S-glass as the glass fiber, since the S-glass includes higher contents of SiO₂ as compared to the E-glass, the FRP has a temperature expansion coefficient lower than that of the E-glass. An FRP substrate including the E-glass or the S-glass has a retardation value of about 5 nm because the FRP substrate is not subject to an elongation process, and is, therefore, suitable for use as the substrates 110 and 130.

When the first and second substrates 110 and 130 are flexible substrates, a completed LCD has increased flexibility. According to an embodiment, only one of the first and second substrates 110 and 130 may be the flexible substrate. When only one of the two substrates 110 and 130 is the flexible substrate, the remaining substrate may be a conventional substrate including glass or quartz, and the spacer 140 is integrally formed on the flexible substrate as a whole between the first and second substrates 110 and 130.

In an embodiment, a plurality of spacers 140 are provided on the second substrate 130. According to an embodiment, the spacers can be provided on the first substrate or both of the first and second substrates.

Since the spacer 140 is to maintain a cell gap between the two substrates, the height of the spacer 140 can be adjusted according to the driving scheme of the LCD 110 and the type of liquid crystal. For example, the spacer 140 may have a height of about 2 μm to about 10 μm from the upper surface of the second substrate 130.

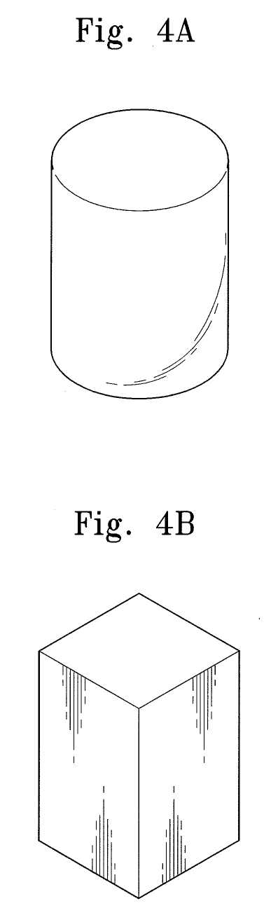

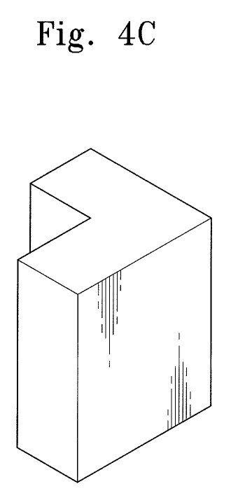

FIGS. 4A to 4C are perspective views illustrating the various shapes of the spacer according to exemplary embodiments of the present invention, in which the spacer has cylindrical, hexahedral, and polyhedral shapes, respectively. As illustrated in FIGS. 4A to 4C, the spacer 140 may have various areas with various shapes. For instance, the spacer 140 may have a cylindrical shape, an oval cylindrical shape, or a polygonal shape such that the spacer 140 has a circular, an oval or a semicircular section on a plane thereof parallel to the upper surface of the substrate. The spacer 140 may have a width (diameter in the case of a circle or the longest diagonal line in the case of a polygon) of about 2 μm to about 20 μm.

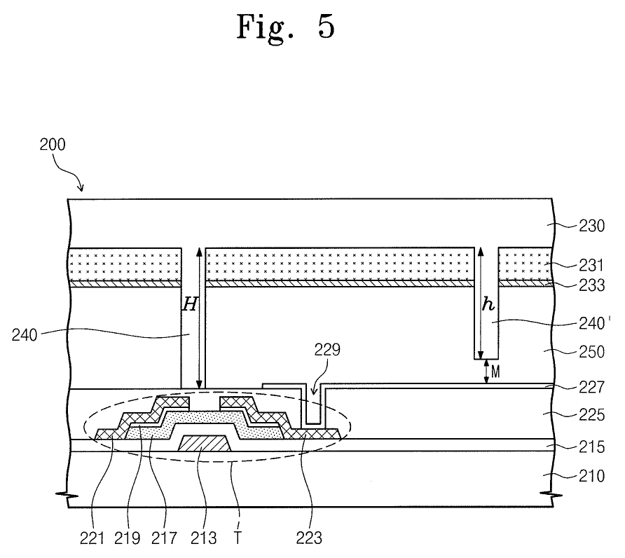

In exemplary embodiments, the spacers 140 have the same height in all pixels to maintain a predetermined cell gap. However, according to an embodiment, spacers may have heights different from each other in a pixel region, or in different pixel regions. FIG. 5 is a sectional view illustrating an LCD according to an exemplary embodiment of the present invention. In this embodiment, the LCD 200 includes spacers having heights different from each other.

Referring to FIG. 5, two spacers 240 and 240′, having first and second heights H and h, respectively, are provided. The heights H and h are different from each other. The LCD 200 having the two spacers 240 and 240′ can be applied to, for example, a touchscreen panel in which information is input through a touch panel. Further, the spacer 240′ is formed with a sufficient margin M considering the degree of bending of a substrate due to touching at a contact area on the LCD.

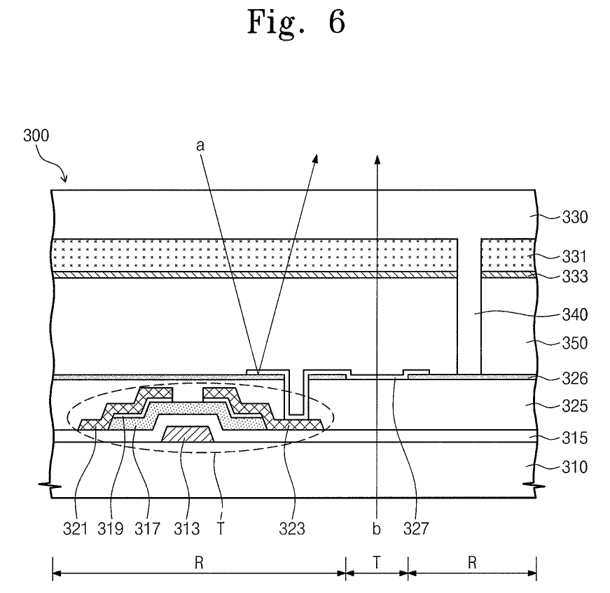

The spacers may be randomly positioned on the substrate. Alternatively, the spacers can be positioned at predetermined places. FIG. 6 illustrates the position of the spacer according to an exemplary embodiment of the present invention.

Referring to FIG. 6, a transflective type LCD 300 is provided. Since liquid crystal does not emit light by itself, light can be provided using a backlight unit. The transflective type LCD 300 can use light from the backlight unit and external natural light or artificial light. In the transflective type LCD 300, each pixel includes a reflecting region R and a transmitting region T. A reflective electrode 326 is formed only in the reflecting region R. The pixel electrode 327 is provided across the transmitting region T and the reflecting region R of the pixel. In the transflective type LCD 300, light ‘b’ emitted from the backlight unit passes through the transmitting region T and light ‘a’ is reflected by the reflecting region R out of the transflective type LCD 300.

A spacer 340 is provided on the reflecting region R. If the spacer 340 is formed on the transmitting region T, luminance can be reduced because transmitted light is blocked by the spacer 340. On the contrary, if the spacer 340 is formed on the reflecting region R, the reduction of luminance is relatively small.

According to an embodiment, the spacer can be positioned on an area where a black matrix (not shown) is formed.

A method of fabrication of the LCD 100 according to an embodiment will be described with reference to FIGS. 1 and 2.

A method of fabrication the LCD 100 includes preparing the first substrate 110 having a plurality of pixels and the second substrate 130 facing the first substrate 110, and forming the liquid crystal layer 150 between the first and second substrates 110 and 130. At least one of the two substrates is a flexible substrate. According to an embodiment, the two substrates are FRP substrates.

In the step of preparing the second substrate 130, a preliminary substrate is prepared and the spacers 140 are simultaneously formed as a whole on the preliminary substrate by using a transfer method.

Glass fiber, yarn or cloth is pre-impregnated with organic resin, such as epoxy, to form the preliminary substrate to make a “pre-preg”, which is a term referring to pre-impregnated fibers. The fiber may be woven in the form of yarn. The preliminary substrate is cut to a predetermined size.

Then, the preliminary substrate is compressed using a press plate having a concave-convex pattern on one surface thereof so that the pattern is transferred onto the surface of the preliminary substrate. The press plate serves as a press tool that compresses the pre-preg. The press plate includes on one surface thereof a transfer pattern that contacts the pre-preg. The transfer pattern corresponds to a pattern to be formed on a target surface.

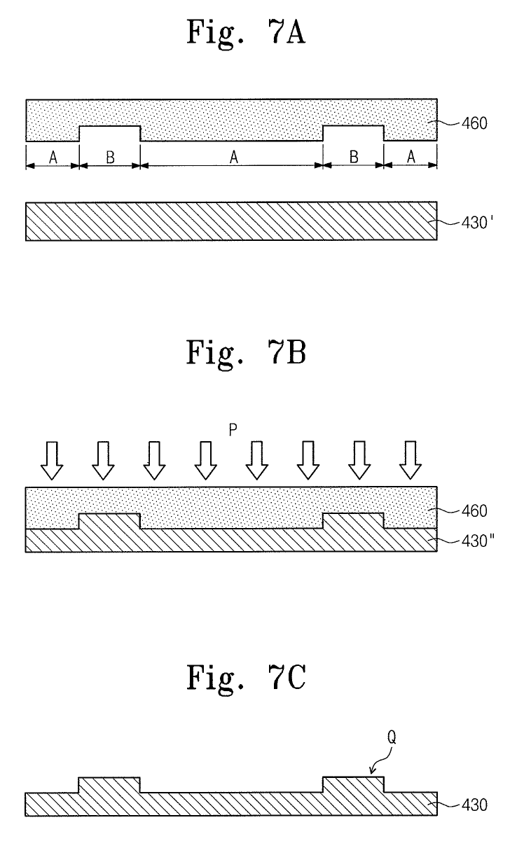

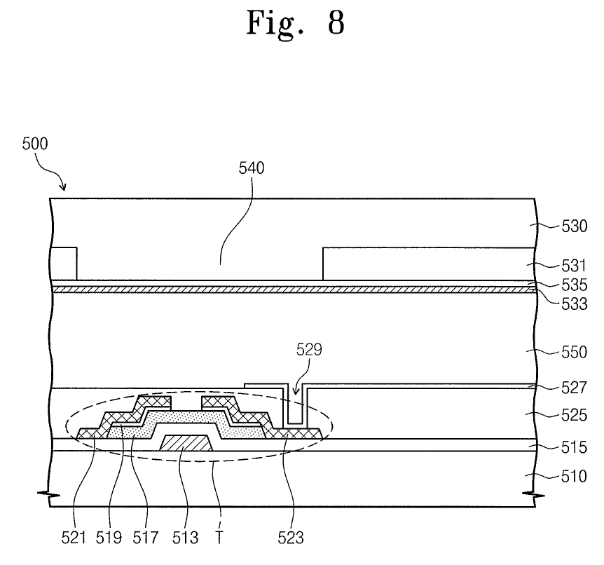

FIGS. 7A to 7C are sectional views schematically illustrating a process for preparing the second substrate having the spacer.

A substrate 430 shown in FIGS. 7A to 7C corresponds to the second substrate 130 and a convex section Q corresponds to the spacer 140.

Referring to FIGS. 7A to 7C, a press plate 460 including a pattern, which has a concave section B and a convex section A, is spaced apart from the upper portion of a first preliminary substrate 430′ (see FIG. 7A).

Next, the press plate 460 makes contact with the upper surface of the first preliminary substrate 430′ and compresses the upper surface of the first preliminary substrate 430′ at predetermined pressure P (see FIG. 7B). Thus, liquid phase resin is shifted from a contact part between the first preliminary substrate 430′ and the press plate 460 to the concave section B of the press plate 460, and the pattern of the press plate 460 is transferred onto the upper surface of the first preliminary substrate 430′. Simultaneously, the volume of the first preliminary substrate 430′ is reduced due to the pressure P to form a second preliminary substrate 430″.

Then, the second preliminary substrate 430″ is cured by heating the second preliminary substrate 430″. The curing process can be simultaneously performed when the first preliminary substrate 430′ is compressed. The pressure and temperature applied to the first preliminary substrate 430′ can be adjusted in consideration of various factors such as strength and transparency of the substrate to be generated. According to an embodiment, the first preliminary substrate 430′ is compressed such that the volume of the first preliminary substrate 430′ is reduced by about 80%, and then the curing process is carried out.

Thereafter, the cured substrate 430″ is separated from the press plate 460 (see FIG. 7C). The material of the press plate 460 can be determined to facilitate separation of the cured substrate 430″ from the press plate 460. In addition or alternatively, the surface of the press plate 460 can be subject to pre-treatment to allow for easier separation of the cured substrate 430″ from the press plate 460. For example, when epoxy resin is used for the pre-preg, hydrophobic material can be coated onto the surface of the press plate 460 such that the press plate 460 can be easily separated from the epoxy resin.

According to an embodiment, the cured substrate 430″ has thickness of about 80 μm to satisfy flexibility and reliability as a substrate, so that the cured substrate 430″ is flexible enough to be used for a flexible LCD, and so that the cured substrate 430″ has a thickness sufficient to provide proper reliability against crushing. In the case of forming the substrate 430″ having the thickness of about 80 μm by using the method as described above, a density of organic resin on the surface of the substrate 430″ is relatively high and a fiber part woven in the form of yarn has a high density at the inner side of the substrate 430″ rather than at the surface thereof. More specifically, the substrate cured in order of a resin layer, a mixture of resin and fiber, and a resin layer in a direction perpendicular to an extension surface of the substrate can be obtained. The resin layer aligned closely to the surface of the substrate may have thickness of about 10 μm and the mixture of resin and fiber may have thickness of about 40 μm to about 60 μm. The convex section Q is formed on the resin layer having a high resin density.

In an embodiment of the present invention, the first substrate 110 having no spacer is compressed using a press plate having no pattern and is cured at the high temperature.

Then, the first and second substrates 110 and 130 are subject to a thin film transistor array process and a color filter process, respectively. In the array process, the gate and data lines 111 and 112 that define a plurality of pixels on the first substrate 110 are formed, the thin film transistor T is formed at a pixel area, and the pixel electrode 127 electrically connected with the thin film transistor T is formed. In the color filter process, the color filter 131 is formed on the second substrate 130 and the common electrode 133 is formed on the color filter 131. In the case of forming the common electrode 133, the common electrode 133 may be provided on an area where the spacer 140 is not formed. An additional photolithography process can be used to pattern the common electrode 133. Further, in the case of a vertical alignment LCD, in which a process of patterning a common electrode is performed, the common electrode can also be patterned on the area where the spacer is formed.

In the process of forming the color filter 131 and the common electrode 133 on the second substrate 130, a polishing for adjusting a height of the spacer 140 may be additionally performed.

The liquid crystal layer 150 is then formed between the first and second substrates 110 and 130.

The present invention is not limited to the embodiment where the concave-convex section forms the spacer on a substrate. In detail, various modifications can be made based on the disclosure as described above. For example, embodiments according to the present invention include various structures in addition to the spacer. FIG. 8 is a sectional view schematically illustrating an LCD according to an exemplary embodiment of the present invention. According to the embodiment illustrated in FIG. 8, a concave-convex section formed on a surface of a second substrate 530 is used as a partition for color filters 531.

Referring to FIG. 8, a concave-convex section is provided on one surface of the second substrate 530, which faces a first substrate 510. A convex section 540 is formed along a peripheral portion of each pixel to serve as a partition surrounding the color filters 531. In more detail, the convex section 540 is formed on an area (that is, around the pixel) corresponding to an area on which a light blocking black matrix is to be formed.

The color filter 531 is provided in the pixel surrounded by the convex section 540 to allow transmitted light to produce a predetermined color. The convex section 540 divides the color filters 531 corresponding to each pixel. Color filter material can be dropped into an area surrounded by the convex section 540 by using an inkjet method, so that the color filters 531 can be formed.

Conventionally, the color filters may be formed using a photolithography process several times. However, according to an embodiment of the present invention, the convex section 540 can be manufactured using only a single process of preparing a substrate similarly to the method of fabrication of the spacer using the concave-convex pattern.

A planar layer 535 may be formed under the color filters 531 and the convex section 540 to planarize the surfaces of the color filters 531 and the convex section 540.

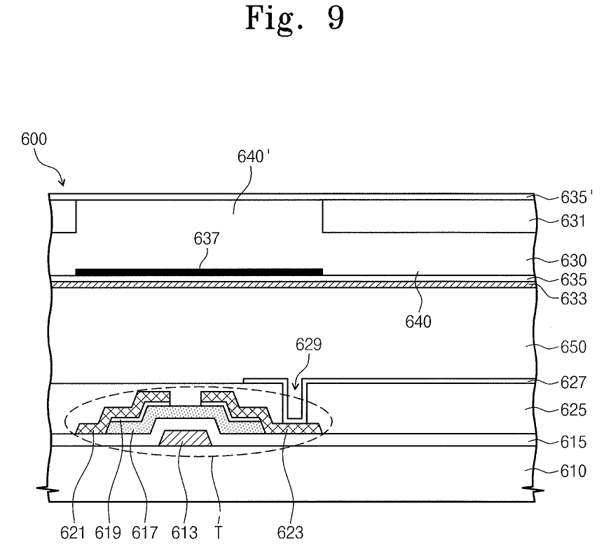

The concave-convex section can also be formed on more than one surface of the second substrate. FIG. 9 is a sectional view schematically illustrating an LCD including the second substrate having the concave-convex sections on both surfaces thereof according to an exemplary embodiment of the present invention.

Referring to FIG. 9, the concave-convex sections are formed on one surface of the second substrate 630, which faces a first substrate 610, and another surface of the second substrate 630, respectively. A convex section 640′ on the other surface of the second substrate 630 is formed as a partition that protrudes from the peripheral portion of the pixel. In more detail, the concave-convex sections on the one surface and the other surface of the second substrate 630 are formed at positions substantially corresponding to each other. A concave section is formed on the other surface of the second substrate 630 corresponding to a convex section 640 on the one surface of the second substrate 630, and the convex section 640′ is formed on the other surface of the second substrate 630 corresponding to a concave section on the one surface of the second substrate 630.

Color filters 631 are formed in a pixel surrounded by the concave section (i.e. the convex section 640′) on the other surface of the second substrate 630. Further, a black matrix 637 is formed on the concave section (formed at the peripheral portion of the pixel) on the one surface of the second substrate 630.

Planar layers 635 and 635′ can be formed on the black matrix 637 and the convex section 640, which are formed on the one surface of the second substrate 630, and on the color filter 631 and the convex section 640′ formed on the other surface of the second substrate 630, thereby planarizing the surfaces of the black matrix 637 and the convex section 640 and the surfaces of the color filter 631 and the convex section 640′, respectively.

The second substrate 630 may be formed by a similar method as illustrated in FIGS. 7A to 7C, and can be formed through a single process of compressing both surfaces of the preliminary substrate using press plates having patterns different from each other. Further, the partition can be easily formed such that the color filter and the black matrix can be formed using the inkjet method, so that the fabrication process and time can be significantly reduced.

Referring to FIG. 9, the black matrix is formed on the one surface of the second substrate and the color filter is formed on the other surface of the second substrate. Alternatively, the black matrix can be formed on the other surface of the second substrate and the color filter is formed on the one surface of the second substrate.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A display apparatus comprising:
a first substrate having a plurality of pixels;
a second substrate facing the first substrate; and
a concave-convex part integrally formed on at least one of the first and second substrates,
wherein the substrate having the concave-convex part is a flexible substrate.

2. The display apparatus of claim 1, wherein the flexible substrate is a plastic substrate.

3. The display apparatus of claim 2, wherein the flexible substrate is a fiber reinforced plastic (FRP) substrate.

4. The display apparatus of claim 1, further comprising:
a plurality of gate lines on the first substrate;
a plurality of data lines crossing the gate lines; and
a thin film transistor formed respectively in each pixel.

5. The display apparatus of claim 4, wherein the concave-convex part comprises a plurality of spacers.

6. The display apparatus of claim 5, wherein the spacers are formed on the second substrate.

7. The display apparatus of claim 6, further comprising a color filter formed on the second substrate.

8. The display apparatus of claim 5, wherein the pixel comprises a reflecting region and a transmitting region, and the spacers are formed in the reflecting region.

9. The display apparatus of claim 5, wherein at least two of the spacers have heights that are different from each other.

10. The display apparatus of claim 5, wherein the spacers are formed in one of a cylindrical shape and a polyhedral column shape.

11. The display apparatus of claim 10, wherein the cylindrical shape is one of an oval cylindrical shape and a semicircular cylindrical shape.

12. The display apparatus of claim 5, wherein the spacers have heights of about 2 μm to about 10 μm and widths of about 2 μm to about 20 μm.

13. The display apparatus of claim 4, wherein the concave-convex part is formed on a surface of the second substrate and comprises a convex section formed at a peripheral portion of each pixel.

14. The display apparatus of claim 13, further comprising a color filter formed in each pixel and surrounded by the convex section.

15. The display apparatus of claim 4, wherein the concave-convex part is formed on two surfaces of the second substrate, and the concave-convex part formed on a first surface of the second substrate comprises a convex section surrounding each pixel, and the concave-convex part formed on a second surface of the second substrate comprises a concave section corresponding to the convex section surrounding each pixel.

16. The display apparatus of claim 15, further comprising:
a color filter surrounded by the convex section formed on the first surface of the second substrate; and
a black matrix formed on the concave section on the second surface of the second substrate.

17. A liquid crystal display comprising:
a first substrate;
a second substrate facing the first substrate;
a liquid crystal layer formed between the first and second substrates; and
a plurality of spacers integrally formed on at least one of the first and second substrates,
wherein the substrate having the spacers is a flexible substrate.

18. A method of manufacturing a display apparatus, the method comprising:
preparing a first substrate having a plurality of pixels; and
preparing a second substrate facing the first substrate;
wherein the preparing of at least one of the first and second substrates comprises:
preparing a preliminary substrate; and
forming concave-convex sections on the preliminary substrate by using a transfer process.

19. The method of claim 18, wherein the substrate having the concave-convex sections is a flexible substrate.

20. The method of claim 18, wherein the preliminary substrate is formed by pre-impregnating resin into fibers.

21. The method of claim 18, wherein the forming of the concave-convex sections comprises:
compressing the preliminary substrate with a press plate having a concave-convex pattern thereon and transferring the concave-convex pattern onto the preliminary substrate; and
curing the preliminary substrate by heating the preliminary substrate.

22. The method of claim 21, wherein the transferring and the curing are performed in a single process.

23. The method of claim 18, further comprising:
forming gate lines and data lines crossing each other on the first substrate; and
forming a thin film transistor in each pixel.

24. The method of claim 23, wherein the concave-convex sections are formed one surface or two surfaces of the preliminary substrate.

25. The method of claim 24, wherein each concave-convex section provided at a surface of the preliminary substrate includes a convex section surrounding a peripheral portion of each pixel.

26. The method of claim 25, further comprising forming a color filter surrounded by the convex section in each pixel.

27. The method of claim 26, wherein the color filter is formed using an inkjet method.

28. The method of claim 24, wherein each concave-convex section provided at a surface of the preliminary substrate comprises a concave section recessed in a peripheral portion of each pixel.

29. The method of claim 28, further comprising forming a black matrix in the concave section.

30. The method of claim 18, further comprising polishing the concave-convex sections to adjust heights of the concave-convex sections.

31. A method of manufacturing a display apparatus, the method comprising:
preparing first and second substrates;
wherein the preparing of at least one of the first and second substrates comprises:
preparing a preliminary substrate; and
forming concave-convex sections on the preliminary substrate by using a transfer process.
